(19) United States
(12) Patent Application Publication
(10) Pub. No.: US 2013/0056154 A1
(43) Pub. Date: Mar. 7, 2013

(54) ABNORMALITY DETECTING UNIT AND ABNORMALITY DETECTING METHOD

(71) Applicants: Michiko NAKAYA, Toyama-City (JP); Haruki OMINE, Sapporo City (JP); Tetsu TSUNAMOTO, Kurokawa (JP); Hiroshi NAGAIKE, Nirasaki City (JP)

(72) Inventors: Michiko NAKAYA, Toyama-City (JP); Haruki OMINE, Sapporo City (JP); Tetsu TSUNAMOTO, Kurokawa (JP); Hiroshi NAGAIKE, Nirasaki City (JP)

(73) Assignee: Tokyo Electron Limited, Tokyo (JP)

(21) Appl. No.: 13/534,594

(22) Filed: Jun. 27, 2012

Related U.S. Application Data
(60) Provisional application No. 61/507,619, filed on Jul. 14, 2011.

(30) Foreign Application Priority Data
Jun. 27, 2011 (JP) 2011-141492
Jun. 25, 2012 (JP) 2012-142092

(51) Int. Cl. G01R 31/26; C23F 1/08

(52) U.S. Cl. 156/345.24; 324/762.05

(57) ABSTRACT

An abnormality detecting unit includes a monitoring unit for monitoring an operation from a wafer deviation starting point to a transfer gate valve opening point after performing a plasma process on the wafer and specifying the operation as a wafer deviation operation; an acquisition unit for acquiring a high frequency signal of at least one of a progressive wave and a reflection wave outputted from a directional coupler between a high frequency power supply for applying a high frequency power into a processing chamber and a matching unit or between a lower electrode as a mounting table for mounting thereon the wafer and the matching unit during the wafer deviation operation; an analysis unit for analyzing a waveform pattern of the high frequency signal; and an abnormality determination unit for determining whether there is an abnormal electric discharge based on an analysis result of the waveform pattern.

### CROSS-REFERENCE TO RELATED APPLICATION

This application claims the benefit of Japanese Patent Application Nos. 2011-141492 and 2012-142092 filed on Jun. 27, 2011, and Jun. 25, 2012, respectively, and U.S. Provisional Application Ser. No. 61/507,619 filed on Jul. 14, 2011, the entire disclosures of which are incorporated herein by reference.

### FIELD OF THE INVENTION

The present disclosure relates an abnormality detecting unit and an abnormality detecting method for detecting an abnormal electric discharge in a plasma processing apparatus.

### BACKGROUND OF THE INVENTION

When performing a process on a processing target object such as a semiconductor wafer (hereinafter, referred to as “wafer”) or a substrate with plasma, a gas is introduced into a processing chamber in which a plasma process is performed and to which a high frequency power is applied. Then, the introduced gas is decomposed to generate plasma. The processing target object is processed with the generated plasma.

In the processing chamber in which the plasma is generated, a high frequency electric field is concentrated by various factors and an abnormal electric discharge such as an arc discharge may occur. The abnormal electric discharge may cause an electric discharge mark on a surface of the processing target object or may burn components provided within the processing chamber. Further, the abnormal electric discharge may peel off reaction products adhering to the components provided within the processing chamber, so that particles may be generated.

For these reasons, if the abnormal electric discharge is detected early within the processing chamber, it is necessary to immediately stop an operation of a plasma processing apparatus, in order to prevent the processing target object and the components from being damaged and to prevent particles from being generated.

Therefore, conventionally, there are suggested methods for early detecting the abnormal electric discharge. By way of example, there is suggested a method in which after a wafer is processed, a test process is performed to detect the electric discharge mark by visual observation. However, according to this method, there is a long waiting time between the wafer process and the test process. During the waiting time, non-processed wafers are continuously processed with the plasma. Thus, even if any defect of the wafer is detected during the test process, it takes a certain amount of time to stop the operation of the plasma processing apparatus in which the abnormal electric discharge occurs. Therefore, lots of wafer products are processed in the meantime and lots of inferior chips may be fabricated.

As another method for early detecting the abnormal electric discharge, there is suggested a method in which the abnormal electric discharge is detected from a waveform pattern of an AE (Acoustic Emission) signal by using an AE sensor (see, for example, Patent Document 1).
Patent Document 1: Japanese Patent Laid-open Publication No. 2011-014608

However, since the AE sensor is highly sensitive, the AE signal detected by the AE sensor may contain a noise such as a mechanical vibration caused by opening/closing transfer gate valve and vertically moving a transfer pin in the plasma processing apparatus as well as the signal caused by the plasma abnormal electric discharge. Therefore, the noise contained in the AE signal may cause a decrease in detection accuracy of the abnormal electric discharge in the plasma processing apparatus.

### BRIEF SUMMARY OF THE INVENTION

In view of the foregoing, illustrative embodiments provide an abnormality detecting unit and an abnormality detecting method capable of improving detection accuracy of an abnormal electric discharge.

In accordance with one aspect of an illustrative embodiment, there is an abnormality detecting unit. The abnormality detecting unit includes an acquisition unit configured to acquire a high frequency signal outputted from an RF sensor provided between a matching unit of a high frequency power supply for applying a high frequency power into a processing chamber in which a plasma process is performed on a processing target object and a lower electrode serving as a mounting table for mounting thereon the processing target object, and an AE signal outputted from an AE sensor for detecting acoustic emission occurring in the processing chamber; an analysis unit configured to analyze a waveform pattern of the high frequency signal and a waveform pattern of the AE signal; and an abnormality determination unit configured to determine whether or not there is an abnormal electric discharge based on an analysis result of the waveform pattern of the high frequency signal and an analysis result of the waveform pattern of the AE signal.

The analysis unit may be configured to extract a maximum amplitude of the high frequency signal and a maximum amplitude of the AE signal based on the waveform pattern of the high frequency signal and the waveform pattern of the AE signal. Further, the abnormality determination unit may be configured to determine whether or not there is an abnormal electric discharge by comparing the maximum amplitude of the high frequency signal with a first critical value and by comparing the maximum amplitude of the AE signal with a second critical value.

The RF sensor may be any one of a directional coupler, an RF probe, and a current probe.

In accordance with another aspect of the illustrative embodiment, there is provided an abnormality detecting unit. The abnormality detecting unit includes a monitoring unit configured to monitor an operation from a deviation starting point of a processing target object to an opening point of a transfer gate valve after a plasma process is performed on the processing target object provided in a processing chamber and to specify the operation as a deviation operation of the processing target object; an acquisition unit configured to acquire a high frequency signal of at least one of a progressive wave and a reflection wave outputted from a directional coupler provided between a high frequency power supply for applying a high frequency power into the processing chamber and a matching unit or between a lower electrode serving as a mounting table for mounting thereon the processing target object and the matching unit during the deviation operation of the processing target object; an analysis unit configured to analyze a waveform pattern of the high frequency signal; and an abnormality determination unit configured to determine whether or not there is an abnormal electric discharge based on an analysis result of the waveform pattern of the high frequency signal.

The acquisition unit may be configured to acquire an AE signal outputted from an AE sensor for detecting the acoustic emission (AE) occurring in the processing chamber. Further, the analysis unit may be configured to analyze a waveform pattern of the AE signal. Furthermore, the abnormality determination unit may be configured to determine whether or not there is an abnormal electric discharge based on the analysis result of the waveform pattern of the high frequency signal and an analysis result of the waveform pattern of the AE signal.

The analysis unit may be configured to extract a maximum amplitude of the high frequency signal and a maximum amplitude of the AE signal based on the waveform pattern of the high frequency signal and the waveform pattern of the AE signal during the deviation operation of the processing target object. Further, the abnormality determination unit may be configured to determine whether or not there is an abnormal electric discharge by comparing the maximum amplitude of the high frequency signal with a first critical value and by comparing the maximum amplitude of the AE signal with a second critical value.

The abnormality determination unit may be configured to determine whether or not there is an abnormal electric discharge by comparing a maximum amplitude generation time of the high frequency signal with a maximum amplitude generation time of the AE signal.

The analysis unit may be configured to perform a frequency analysis on the waveform pattern of the AE signal, remove a noise from the frequency-analyzed data by using a noise removing filter, and analyze the noise-removed data.

The AE sensor may be provided at a power supply rod that supplies a high frequency power to the lower electrode serving as the mounting table for mounting thereon the processing target object.

Sampling of the high frequency signal may be performed at intervals ranging from every 1 μsec to every 5 μsec.

Sampling of the AE signal may be performed at intervals ranging from every 1 μsec to every 1 msec.

When a DC high voltage power applied to an electrode embedded in an electrostatic chuck is off or when the DC high voltage power is reversely applied, the monitoring unit may determine that it is the deviation starting point of the processing target object after the plasma process is performed.

In accordance with still another aspect of the illustrative embodiment, there is provided an abnormality detecting method. The abnormality detecting method includes acquiring a high frequency signal outputted from an RF sensor provided between a matching unit of a high frequency power supply for applying a high frequency power into a processing chamber in which a plasma process is performed on a processing target object and a lower electrode serving as a mounting table for mounting thereon the processing target object, and an AE signal outputted from an AE sensor for detecting acoustic emission occurring in the processing chamber; analyzing a waveform pattern of the high frequency signal and a waveform pattern of the AE signal; and determining whether or not there is an abnormal electric discharge based on an analysis result of the waveform pattern of the high frequency signal and an analysis result of the waveform pattern of the AE signal.

In accordance with still another aspect of the illustrative embodiment, there is provided an abnormality detecting method. The abnormality detecting method includes monitoring an operation from a deviation starting point of a processing target object to an opening point of a transfer gate valve after a plasma process is performed on the processing target object provided in a processing chamber and specifying the operation as a deviation operation of the processing target object; acquiring a high frequency signal of at least one of a progressive wave and a reflection wave outputted from a directional coupler provided between a high frequency power supply for applying a high frequency power into the processing chamber and a matching unit or between a lower electrode serving as a mounting table for mounting thereon the processing target object and the matching unit during the deviation operation of the processing target object; analyzing a waveform pattern of the high frequency signal; and determining whether or not there is an abnormal electric discharge based on an analysis result of the waveform pattern of the high frequency signal.

In accordance with still another aspect of the illustrative embodiment, there is provided a plasma processing apparatus. The plasma processing apparatus includes a processing chamber configured to process a substrate therein; a plasma generating unit configured to generate plasma in the processing chamber; and an abnormal electric discharge detecting unit connected to a power supply unit of the plasma generating unit and configured to detect an abnormality of the plasma. The abnormal electric discharge detecting unit may include an acquisition unit configured to acquire a high frequency signal outputted from an RF sensor provided between a matching unit of a high frequency power supply for applying a high frequency power into a processing chamber in which a plasma process is performed on a processing target object and a lower electrode serving as a mounting table for mounting thereon the processing target object, and an AE signal outputted from an AE sensor for detecting acoustic emission occurring in the processing chamber; an analysis unit configured to analyze a waveform pattern of the high frequency signal and a waveform pattern of the AE signal; and an abnormality determination unit configured to determine whether or not there is an abnormal electric discharge based on an analysis result of the waveform pattern of the high frequency signal and an analysis result of the waveform pattern of the AE signal.

In accordance with the illustrative embodiments, it is possible to provide an abnormality detecting unit and an abnormality detecting method capable of improving detection accuracy of the abnormal electric discharge.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a longitudinal cross sectional view of an etching apparatus in accordance with an illustrative embodiment;

FIG. 2 is a functional configuration view of a controller for the etching apparatus in accordance with the illustrative embodiment;

FIG. 3 is a flow chart showing a data acquisition process in accordance with the illustrative embodiment;

FIG. 4 is a graph illustrating an example of an abnormal waveform generated in the etching apparatus in accordance with the illustrative embodiment;

FIG. 5 is a flow chart showing an abnormality detecting process in accordance with the illustrative embodiment;

FIG. 6 illustrates a waveform pattern of a high frequency signal for each wafer in accordance with the illustrative embodiment;

FIG. 7 illustrates a maximum amplitude of the high frequency signal for each wafer in accordance with the illustrative embodiment;

FIG. 8 illustrates a waveform pattern of an AE signal for each wafer in accordance with the illustrative embodiment;

FIG. 9 illustrates a waveform pattern after performing a frequency analysis of the AE signal, for each wafer in accordance with the illustrative embodiment;

FIG. 10 illustrates a maximum amplitude of the AE signal for each wafer in accordance with the illustrative embodiment;

FIG. 11 illustrates a difference between a maximum amplitude generation time of a high frequency signal and a maximum amplitude generation time of an AE signal in accordance with the illustrative embodiment;

FIG. 12 is a longitudinal cross sectional view of an etching apparatus in accordance with another illustrative embodiment;

FIG. 13 illustrates a waveform pattern of a high frequency signal detected from an RF probe and a waveform pattern of an AE signal in accordance with the illustrative embodiment; and

FIG. 14 is a flow chart showing an abnormality detecting process in accordance with a modification example.

### DETAILED DESCRIPTION OF THE INVENTION

Hereinafter, illustrative embodiments will be described in detail with reference to the accompanying drawings. In the specification and drawings, parts having substantially the same functions and configurations will be assigned same reference numerals, and redundant description will be omitted.

[Apparatus Configuration]

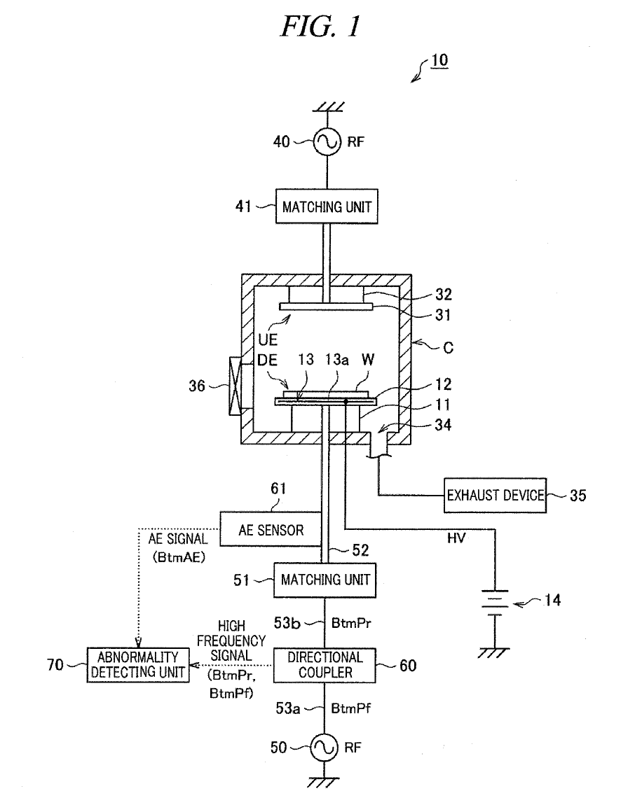

Firstly, configuration of an etching apparatus as an example of a plasma processing apparatus in accordance with an illustrative embodiment will be explained with reference to FIG. 1. FIG. 1 is a longitudinal cross sectional view of the etching apparatus in accordance with the illustrative embodiment.

An etching apparatus 10 is a capacitively coupled etching apparatus in which electrode plates are provided to face each other in parallel. The etching apparatus 10 includes a cylindrical processing chamber C made of, for example, aluminum of which a surface is anodically oxidized. The processing chamber C is grounded. At a bottom portion of the processing chamber C, there is provided a substantially cylindrical susceptor support 11 for mounting thereon a wafer W via a ceramic insulating plate (not illustrated). A mounting table 12 serving as a lower electrode DE is provided on the susceptor support 11.

An electrostatic chuck 13 is provided at the lower electrode DE to hold the wafer W on the lower electrode DE. An electrode 13a of the electrostatic chuck 13 is formed of a thin film made of, for example, polyimide and embedded in the lower electrode DE. When DC voltage outputted from a DC high voltage power supply 14 is applied to the electrode 13a, the wafer W mounted on a surface of the mounting table 12 is attracted to and held on the lower electrode DE by an electrostatic attracting force.

In the susceptor support 11, the mounting table 12, and the electrostatic chuck 13, there is provided a non-illustrated gas passage for supplying a heat transfer medium (for example, a He gas) to a rear surface of the wafer W. Cold heat of the mounting table 12 is transferred to the wafer W via the heat transfer medium, so that the wafer W can be controlled to have a certain temperature.

Above the mounting table 12, there is provided an upper electrode UE facing the lower electrode DE. The upper electrode UE is supported at a ceiling portion of the processing chamber C. The upper electrode UE includes an upper electrode plate 31 and an electrode support body 32 configured to support the upper electrode plate 31 and made of a conductive material.

An etching gas used for a plasma etching process is supplied to the processing chamber C through a non-illustrated gas path. The bottom portion of the processing chamber C is connected to an exhaust device 35 via an exhaust pipe 34. The exhaust device 35 includes a vacuum pump such as a turbo molecular pump for evacuating the inside of the processing chamber C to be in a certain depressurized atmosphere. At a sidewall of the processing chamber C, there is provided a transfer gate valve 36. By opening and closing the transfer gate valve 36, the wafer W is transferred between a transfer chamber (not illustrated) and the processing chamber C.

The etching apparatus 10 applies two high frequency powers to the upper electrode and the lower electrode, respectively. The upper electrode UE is connected to a first high frequency power supply 40 via a matching unit 41. The first high frequency power supply 40 applies a high frequency power of a frequency (RF) in a range of, from about 27 MHz to about 150 MHz. While the etching gas is supplied, the first high frequency power is applied between the upper electrode UE and the lower electrode DE, so that desired plasma of the etching gas can be generated within the processing chamber C.

The mounting table 12 serving as the lower electrode DE is connected to a second high frequency power supply 50 via a matching unit 51. The matching unit 51 and the lower electrode DE are connected by a power supply rod 52. A directional coupler 60 is provided between the second high frequency power supply 50 and the matching unit 51. The second high frequency power supply 50 and the matching unit 51 are connected by coaxial cables 53a and 53b. The second high frequency power supply 50 applies, to the lower electrode DE, the second high frequency power for bias having a frequency lower than that of the first high frequency power supply 40. Thus, the wafer W can be affected by an appropriate ionic action without being damaged. Desirably, the second high frequency power supply 50 applies a power of a frequency in a range of, from about 1 MHz to about 20 MHz. The directional coupler 60 may be provided between the lower electrode DE serving as the mounting table for mounting the wafer W and the matching unit 51.

In the above-described configuration, the etching gas supplied into the processing chamber C is exited into plasma by the first high frequency power outputted from the first high frequency power supply 40. An etching process is performed on the wafer W on the mounting table 12 with the generated plasma.

[Abnormal Electric Discharge Detection]

Hereinafter, abnormal electric discharge detection of the etching apparatus 10 will be explained.

During the etching process performed by the etching apparatus 10, when the second high frequency power is applied to the wafer W from the second high frequency power supply 50 via the coaxial cable 53a, the directional coupler 60, the coaxial cable 53b, the matching unit 51, and the power supply rod 52, an abnormal electric discharge (for example, an arc discharge) may occur within the processing chamber C. In this case, impedance of the plasma becomes non-uniform and a reflection wave BtmPr traveling from the matching unit 51 toward the second high frequency power supply 50 may be generated. The directional coupler 60 detects the reflection wave BtmPr traveling from the matching unit 51 toward the second high frequency power supply 50. Further, the directional coupler 60 may detect a progressive wave BtmPf traveling from the second high frequency power supply 50 toward the matching unit 51. However, the directional coupler 60 may detect at least one of the progressive wave BtmPf and the reflection wave BtmPr. Hereinafter, a signal of at least one of the progressive wave BtmPf and the reflection wave BtmPr detected by the directional coupler 60 will be referred to as “high frequency signal”.

An AE sensor 61 is provided at a ground line of the power supply rod 52 by, for example, an adhesive. The AE sensor 61 detects AE (Acoustic Emission) caused by energy emission during the plasma abnormal electric discharge. In the present illustrative embodiment, the AE sensor 61 is provided at an atmospheric space at an outside of the processing chamber C, which is as close as possible to the wafer W in order to accurately detect the abnormal electric discharge on the wafer W. Alternatively, the AE sensor 61 may be provided above the wafer. W. However, it is desirable to provide the AE sensor 61 under the wafer W for easily detecting the abnormal electric discharge on the wafer W.

Since the AE sensor 61 is highly sensitive, an AE signal detected by the AE sensor 61 may contain a noise such as a mechanical vibration caused by opening/closing the transfer gate valve 36 and moving up and down a non-illustrated pin for transferring the mounted wafer W in the etching apparatus 10 as well as a signal caused by the plasma abnormal electric discharge. Therefore, the noise contained in the AE signal may cause a decrease in detection accuracy of the plasma abnormal electric discharge.

Therefore, in the abnormal electric discharge detection in accordance with the present illustrative embodiment, the directional coupler 60 and the AE sensor 61 are provided at the etching apparatus 10, and the high frequency signal detected by the directional coupler 60 and the AE signal detected by the AE sensor 61 are sampled at high speed. Hereinafter, the sampled AE signal will be denoted as “BtmAE”. Further, the sampled high frequency signal of the reflection wave will be denoted as “BtmPr” and the sampled high frequency signal of the progressive wave will be denoted as “BtmPf”.

An abnormality detecting unit 70 acquires the sampled high frequency signal BtmPf and/or BtmPr from the directional coupler 60. Further, the abnormality detecting unit 70 acquires the sampled AE signal BtmAE from the AE sensor 61. The abnormality detecting unit 70 determines whether or not there is an abnormal electric discharge based on analysis results of both a waveform pattern of the high frequency signal and a waveform pattern of the AE signal. Generally, if only AE sensor 61 is used, it is difficult to separate the noise and measurement values of the abnormal electric discharge, which are contained in the AE signal. However, it is possible to remove the noise contained in detection results of the AE sensor 61 by detecting the high frequency signal of the reflection wave or the progressive wave from the directional coupler 60. Further, in the abnormal electric discharge detection in accordance with the present illustrative embodiment, the abnormal electric discharge is detected by using sampled data measured by the directional coupler 60 and the AE sensor 61. The sampled data measured by the AE sensor 61 may not be required, and the abnormal electric discharge may be detected by analyzing only the sampled data detected by the directional coupler 60. However, it is desirable to detect the abnormal electric discharge by using both sampled data for high accuracy.

Desirably, sampling of the high frequency signal is performed at intervals ranging from every 1 μsec to every 5 μsec, and sampling of the AE signal is performed at intervals ranging from every 1 μsec to every 1 msec.

If the sampled data of the AE signal are collected constantly during the plasma process, a large amount of data may be collected. Therefore, if the abnormal electric discharge is detected by analyzing all the collected data, the process load is increased with low efficiency. If it is possible to find out conditions under which the abnormal electric discharge is likely to occur, sampled data satisfying the conditions are collected and only necessary sampled data are analyzed. Accordingly, the process load can be decreased and efficiency becomes high.

(Wafer Deviation)

The present inventors found out through experiments that when the electric charge of the wafer W is eliminated, the abnormal electric discharge is likely to occur on the wafer W. Therefore, in the present illustrative embodiment, sampled data are collected during the wafer deviation during which the abnormal electric discharge is likely to occur on the wafer W. Thus, it is possible to detect the minute abnormal electric discharge that occurs on a front surface of the wafer W and a rear surface of the wafer W. Herein, the term “during the wafer deviation” means a time period from a starting point of the wafer deviation to an ending point of the wafer deviation. To be specific, when output of DC high voltage power HV applied to the electrode 13a of the electrostatic chuck 13 is off or when the DC high voltage power HV is reversely applied, it is set as a condition for the starting point of the wafer deviation after the plasma process. Further, when a pin for moving up and down the wafer W mounted on the mounting table 12 is moved up after the starting point of the wafer deviation and the transfer gate valve 36 is opened, it is set as a condition for the ending point of the wafer deviation.

As described above, in the present illustrative embodiment, the abnormal electric discharge is likely to occur on the wafer W when the output of the DC high voltage power HV is off, when the DC high voltage power HV is reversely applied, when the pin is moved up, and when the transfer gate valve 36 is opened. Therefore, these conditions are included in the time period of the wafer deviation and sampled data are collected in this time period. However, the time period of the wafer deviation is not limited thereto, and may include a time period from an off point of the DC high voltage power HV to an opening/closing point of the transfer gate valve 36, a time period from an off point of the DC high voltage power HV to a moving point of the pin, a time period from a reversely applying point of the DC high voltage power HV to an opening/closing point of the transfer gate valve 36, and a time period from a reversely applying point of the DC high voltage power HV to a moving point of the pin.

[Functional Configuration]

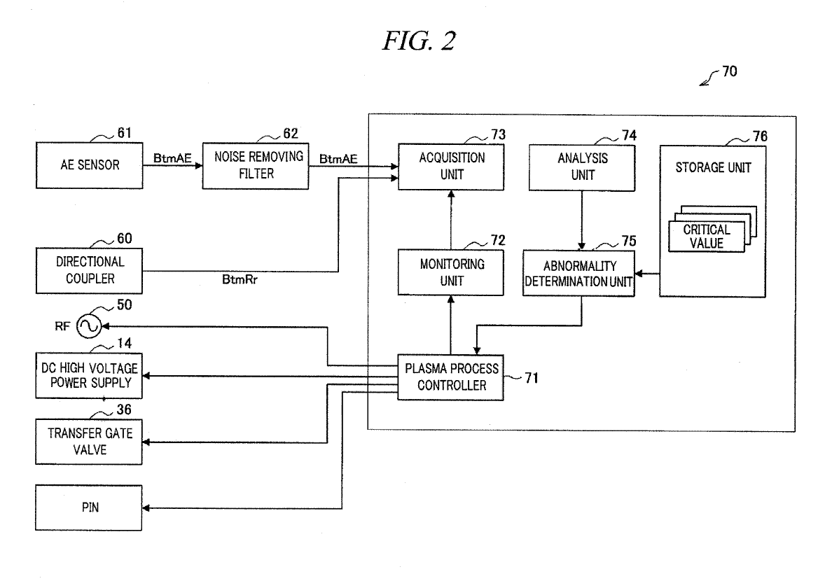

Hereinafter, there will be explained a functional configuration of the abnormality detecting unit 70 with reference to FIG. 2.

The abnormality detecting unit 70 is configured to detect the abnormal electric discharge in the etching apparatus 10. The abnormality detecting unit 70 includes a plasma process controller 71, a monitoring unit 72, an acquisition unit 73, an analysis unit 74, an abnormality determination unit 75, and a storage unit 76. However, the abnormality detecting unit 70 may not include the plasma process controller 71 and the storage unit 76.

The plasma process controller 71 is configured to control an etching process performed in the etching apparatus 10. To be specific, the plasma process controller 71 is configured to control the second high frequency power from the second high frequency power supply 50 and on/off thereof. The plasma process controller 71 is configured to control the DC high voltage power HV from the DC high voltage power supply 14 and on/off thereof. Further, the plasma process controller 71 is configured to open/close the transfer gate valve 36 and vertically move the non-illustrated pin for transferring the wafer W mounted on the mounting table 12.

The monitoring unit 72 is configured to monitor an operation from the starting point of the wafer deviation to the opening point of the transfer gate valve 36 after the plasma process performed on the wafer W mounted in the processing chamber C. This operation is specified as a wafer deviation operation.

In the wafer deviation operation, the acquisition unit 73 acquires the high frequency signal of at least one of the progressive wave and the reflection wave outputted from the directional coupler 60. The directional coupler 60 is provided between the second high frequency power supply for applying the second high frequency power to the processing chamber C and the matching unit 51. Further, the acquisition unit 73 acquires the AE signal outputted from the AE sensor 61 for detecting acoustic emission (AE) occurring in the processing chamber C. The directional coupler 60 may be provided between the first high frequency power supply 40 and the matching unit 41, and the acquisition unit 73 may acquire the high frequency signal of at least one of the progressive wave and the reflection wave outputted from the directional coupler 60.

The analysis unit 74 is configured to analyze a waveform pattern of the high frequency signal. Further, the analysis unit 74 analyzes a waveform pattern of the AE signal. As an example of an analyzing method, the analysis unit 74 may find out and analyze a maximum amplitude of the high frequency signal and a maximum amplitude of the AE signal during the wafer deviation operation based on the waveform pattern of the high frequency signal and the waveform pattern of the AE signal. Furthermore, the analysis unit 74 may perform a frequency analysis FFT (Fast Fourier Transform) on the waveform pattern of the AE signal, remove the noise from the frequency-analyzed data by using a noise removing filter 62, and analyze the noise-removed data.

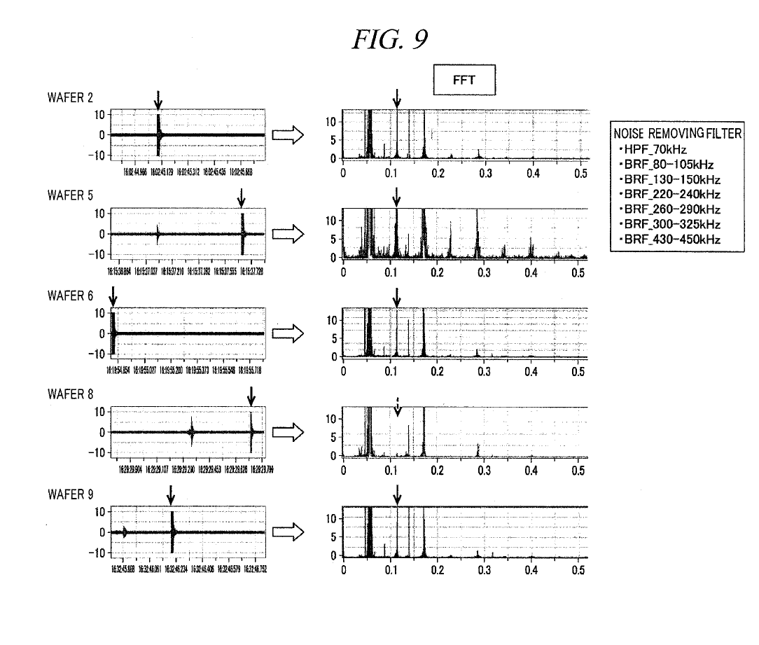

The noise removing filter 62 is used to remove the unnecessary noise from the AE signal. The noise removing filter 62 is configured to remove the noise in a predetermined band. By way of example, as depicted in FIG. 9, the noise removing filter 62 includes a high pass filter HPF that allows only the signal of about 70 kHz or more to pass therethrough and removes the signal out of the band as a noise. Further, the noise removing filter 62 includes a band pass filter BPF that allows only the signal within a desired band to pass therethrough and removes the signal out of the band as a noise. By way of example, in the present illustrative embodiment, a band for the band pass filter BPF is set to be from about 80 kHz to about 105 kHz, from about 130 kHz to about 150 kHz, from about 220 kHz to about 240 kHz, from about 260 kHz to about 290 kHz, from about 300 kHz to about 325 kHz, and from about 430 kHz to about 450 kHz, and the signal out of these bands is removed as a noise.

The analysis unit 74 is configured to sample the AE signal passing through the noise removing filter 62 at high speed with a frequency of, for example, about 1 MHz, convert the sampled AE signal into digital data (high speed sampled data), and store the converted data in the storage unit 76.

The abnormality determination unit 75 is configured to determine whether or not there is an abnormal electric discharge based on an analysis result of the waveform pattern of the high frequency signal. Further, the abnormality determination unit 75 may determine whether or not there is an abnormal electric discharge based on an analysis result of the waveform pattern of the high frequency signal and an analysis result of the waveform pattern of the AE signal. To be specific, the abnormality determination unit 75 may determine whether or not there is an abnormal electric discharge by comparing the maximum amplitude of the high frequency signal with a first critical value (a critical value C to be described later) and by comparing the maximum amplitude of the AE signal with a second critical value (a critical value D to be described later). Further, considering the noise contained in the AE signal, the abnormality determination unit 75 may determine whether or not there is an abnormal electric discharge by comparing a maximum amplitude generation time of the high frequency signal with a maximum amplitude generation time of the AE signal.

The storage unit 76 is configured to store therein various critical values used by the abnormality determination unit 75 in order to determine whether or not there is an abnormal electric discharge. The storage unit 76 may temporarily store therein the sampled data from the AE sensor 61 and the sampled data from the directional coupler 60. The various critical values may be optimized through feedback of an abnormal electric discharge detection result.

The functions of the plasma process controller 71, the monitoring unit 72, the acquisition unit 73, the analysis unit 74, and the abnormality determination unit 75 are performed when, for example, a CPU (Central Processing Unit) carries out a program stored in the storage unit 76. This program may be stored in a storage medium to be read out by the storage unit 76 via a non-illustrated driver or may be downloaded from a non-illustrated network to be stored in the storage unit 76. In order to perform the functions of the respective units, a DSP (Digital Signal Processor) may be employed instead of the CPU. By way of example, the storage unit 76 may include a ROM (Read Only Memory) or a RAM (Random Access Memory) using a semiconductor memory, a magnetic disk, or an optical disk. The functions of the plasma process controller 71, the monitoring unit 72, the acquisition unit 73, the analysis unit 74, and the abnormality determination unit 75 may be performed by using software or hardware.

[Operation: Data Acquisition]

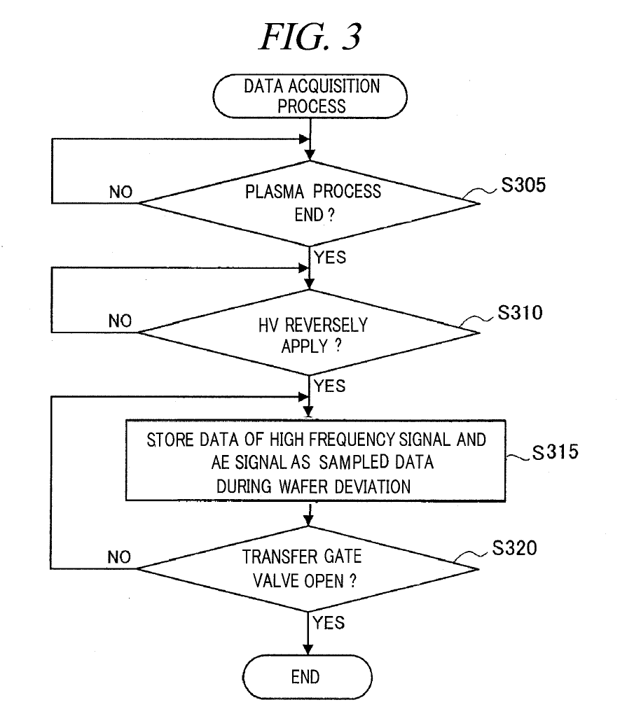

Hereinafter, there will be explained a data acquisition operation of the abnormality detecting unit 70 in accordance with the present illustrative embodiment with reference to FIG. 3. FIG. 3 is a flow chart showing a data acquisition process performed in the abnormality detecting unit 70 in accordance with the present illustrative embodiment.

In the data acquisition process, the acquisition unit 73 firstly determines whether or not the plasma process is ended (step S305). If the plasma process is not ended, the acquisition unit 73 repeats step S305 until the plasma process is ended. If the plasma process is ended, the acquisition unit 73 determines whether or not the DC high voltage power HV from the DC high voltage power supply 14 is off and the DC high voltage power HV is reversely applied (step S310). If the DC high voltage power HV is not reversely applied, the acquisition unit 73 repeats step S310 until the DC high voltage power HV is reversely applied.

If the DC high voltage power HV is reversely applied, the acquisition unit 73 stores data of the high frequency signal and the AE signal in the storage unit 76 as sampled data during the wafer deviation (step S315). Then, the acquisition unit 73 determines whether or not the transfer gate valve 36 for loading/unloading the wafer W is opened (step S320). The acquisition unit 73 acquires sampled data until the transfer gate valve 36 is opened. If the transfer gate valve 36 is opened, the data acquisition process is ended.

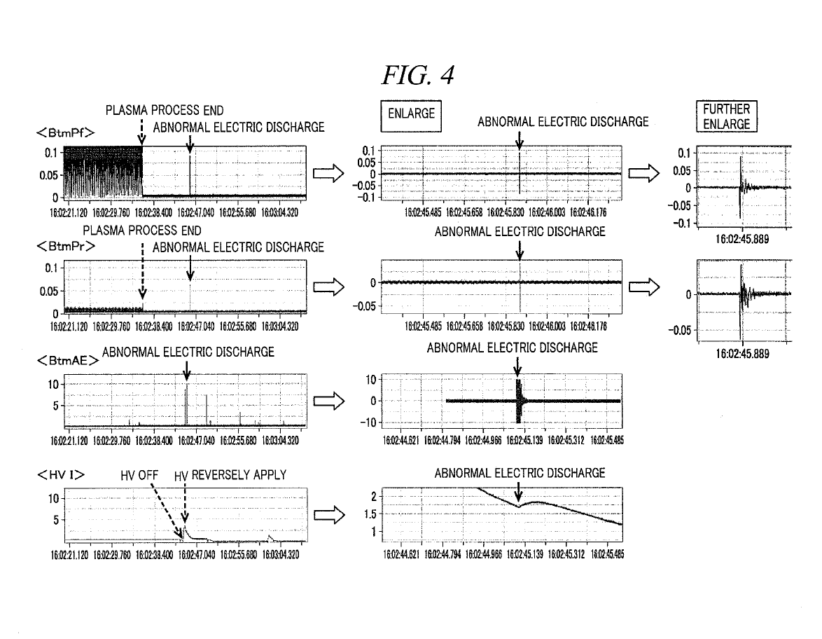

An example of the sampled data acquired through the above-described data acquisition process is shown in FIG. 4. A horizontal axis of each graph in FIG. 4 represents time and a vertical axis thereof represents voltage. Graphs on the left of FIG. 4 show data of the high frequency signal BtmPf of the progressive wave, data of the high frequency signal BtmPr of the reflection wave, data of the AE signal BtmAE, and data of the DC high voltage power HV, respectively, in this sequence from the top.

A voltage value is sharply dropped at some points in the high frequency signal BtmPf of the progressive wave and the high frequency signal BtmPr of the reflection wave. These points indicate time points when the plasma process is ended and when the second high frequency power from the second high frequency power supply 50 is off.

Graphs in the middle of FIG. 4 are enlarged from the graphs on the left of FIG. 4, respectively. It can be seen that while the DC high voltage power HV is off and reversely applied as shown in the undermost graph in the middle of FIG. 4, the abnormal electric discharge on the wafer W indicated by a thick arrow occurs in the high frequency signal BtmPf of the progressive wave, the high frequency signal BtmPr of the reflection wave, and the AE signal BtmAE shown in the top three graphs in the middle of FIG. 4. Graphs on the right of FIG. 4 are further enlarged from the top two graphs in the middle of FIG. 4, respectively. If a wafer defect test is performed separately, the electric discharge mark can be found on a wafer W from which an abnormal waveform shown in FIG. 4 is detected. It can be seen from the above-described experiment result that there is a correlation between the wafer deviation operation and the abnormal electric discharge on the wafer W.

[Operation: Abnormal Electric Discharge Detection]

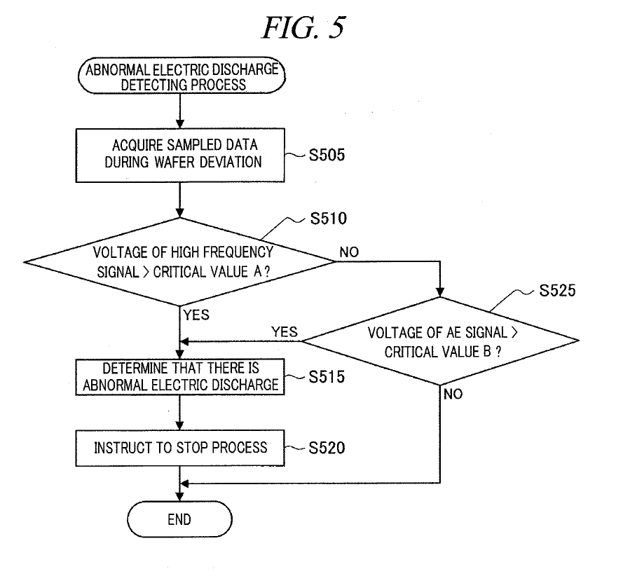

Based on the above-described experiment result, there will be explained the abnormal electric discharge detecting operation of the abnormality detecting unit 70 in accordance with the present illustrative embodiment with reference to FIG. 5. FIG. 5 is a flow chart showing an abnormal electric discharge detecting process performed by the abnormality detecting unit 70 in accordance with the present illustrative embodiment.

In the abnormal discharge detecting process, the analysis unit 74 firstly acquires the sampled data during the wafer deviation acquired by the acquisition unit 73 (step S505). By way of example, the analysis unit 74 reads out the sampled data during the wafer deviation from the storage unit 76.

Then, the abnormality determination unit 75 determines whether or not there is an abnormal peak having a value greater than a predetermined critical value A among the sampled data of the high frequency signals (step S510). If there is an abnormal peak, the abnormality determination unit 75 determines that there is an abnormal electric discharge on the wafer W (step S515) and instructs the plasma process controller 71 to stop the process (step S520), and then the abnormal electric discharge detecting process is ended.

In step S510, if there is no abnormal peak having a value greater than the predetermined critical value A among the sampled data of the high frequency signal, the abnormality determination unit 75 determines whether or not there is an abnormal peak having a value greater than a predetermined critical value B among the sampled data of the AE signal (step S525). If there is no abnormal peak, the abnormal electric discharge detecting process is ended. Meanwhile, if there is the abnormal peak having a value greater than the predetermined critical value B among the sampled data of the AE signal, the abnormality determination unit 75 determines that there is an abnormal electric discharge on the wafer W (step S515) and instructs the plasma process controller 71 to stop the process (step S520), and then the abnormal electric discharge detecting process is ended.

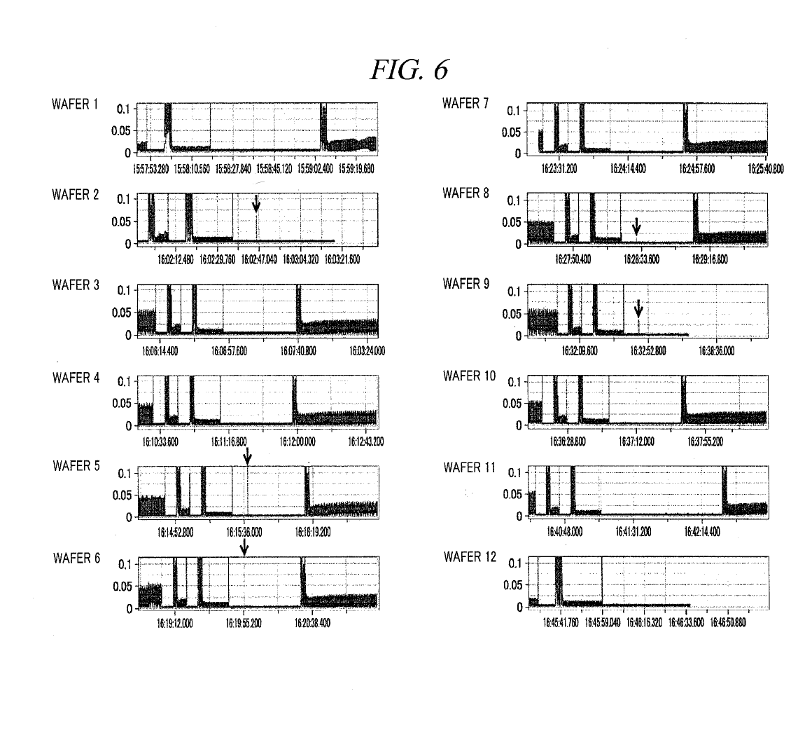

An example of the high frequency signal data used for the above-described abnormal electric discharge detecting process is shown in FIG. 6. A horizontal axis of each graph in FIG. 6 represents time and a vertical axis thereof represents voltage. Graphs of FIG. 6 show data of the high frequency signal BtmPr of the reflection wave in the directional coupler 60 when the DC high voltage power HV is reversely applied to wafers 1 to 12.

It can be seen from the high frequency signal BtmPr of the reflection wave that when the DC high voltage power HV is reversely applied, there is detected a spectrum suspected of the abnormal peak on wafer 2, wafer 5, wafer 6, wafer 8, and wafer 9 (indicated by an arrow in FIG. 6).

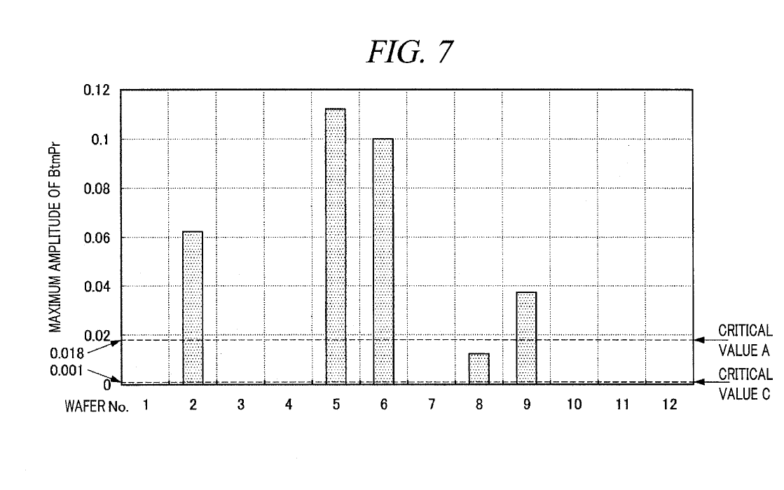

Therefore, the abnormality determination unit 75 compares the maximum amplitude of the high frequency signal with a critical value A (corresponding to the first critical value) in the comparing process of step S510 in order to determine whether or not there is an abnormal electric discharge. FIG. 7 is a graph comparing the maximum amplitude of the high frequency signal BtmPr of the reflection wave and the critical value A. According to FIG. 7, the abnormality determination unit 75 determines that there is an abnormal electric discharge on the wafer 2, the wafer 5, the wafer 6, and the wafer 9 and there is an abnormal electric discharge of low level on the wafer 8. The present inventors check arcing marks with a SEM (Scanning Electron Microscope), and find that the arcing marks generated on the wafer 2, the wafer 5, the wafer 6, and the wafer 9 are greater than the arcing mark generated on the wafer 8. It is determined that there is an abnormal electric discharge if the maximum amplitude of the high frequency signal BtmPr of the reflection wave is greater than the critical value C, and a magnitude of the abnormal electric discharge is corresponds to a magnitude of a voltage value. That is, it is determined that there is an abnormal electric discharge of relatively high level if the maximum amplitude of the high frequency signal BtmPr of the reflection wave is greater than the critical value A. Further, it is determined that there is an abnormal electric discharge of low level if the maximum amplitude of the high frequency signal BtmPr of the reflection wave is greater than the critical value C.

As described above, it can be seen that when the DC high voltage power HV is reversely applied, the wafers on which there is generated an abnormal waveform in the high frequency signal BtmPr of the reflection wave are identical to the wafers on which there is formed an arcing mark. Further, it can be seen that there is a correlation between the maximum amplitude of the high frequency signal BtmPr of the reflection wave and a magnitude of the arcing mark.

In an abnormality detecting method in accordance with the present illustrative embodiment, even if the abnormal electric discharge is detected from only one wafer, the plasma process is controlled to stop immediately. The critical value C will be explained in a following modification example.

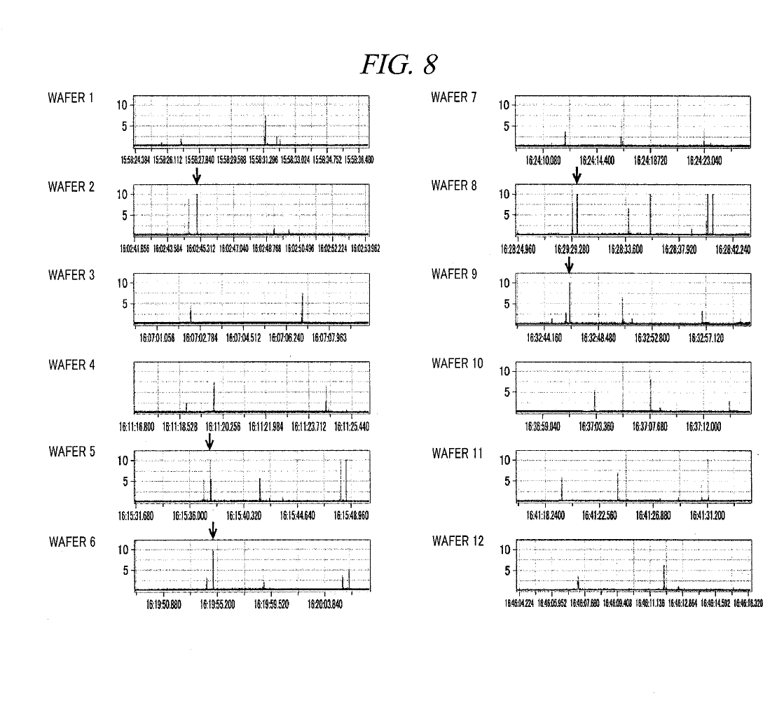

Hereinafter, an example of the AE signal data used for the above-described abnormal electric discharge process is shown in FIG. 8. A horizontal axis of each graph in FIG. 8 represents time and a vertical axis thereof represents voltage. Graphs of FIG. 8 show data of the AE signal BtmAE in the AE sensor 61 when the DC high voltage power HV is reversely applied to the wafers 1 to 12.

It can be seen from the AE signal BtmAE that when the DC high voltage power HV is reversely applied, there is detected a spectrum suspected of the abnormal peak in the wafer 2, the wafer 5, the wafer 6, the wafer 8, and the wafer 9 (indicated by an arrow in FIG. 8).

Therefore, the abnormality determination unit 75 compares the maximum amplitude of the noise-removed AE signal with a critical value B (corresponding to the second critical value) in the comparing process of step S525 in order to determine whether or not there is an abnormal electric discharge. Graphs on the left of FIG. 9 show AE signals for the wafer 2, the wafer 5, the wafer 6, the wafer 8, and the wafer 9, respectively, and graphs in the middle of FIG. 9 show data of frequency-analyzed AE signals for the wafer 2, the wafer 5, the wafer 6, the wafer 8, and the wafer 9, respectively. Arrows in the respective graphs on the left of FIG. 9 and in the respective graphs in the middle of FIG. 9 indicate positions to be determined whether or not there is an abnormal electric discharge.

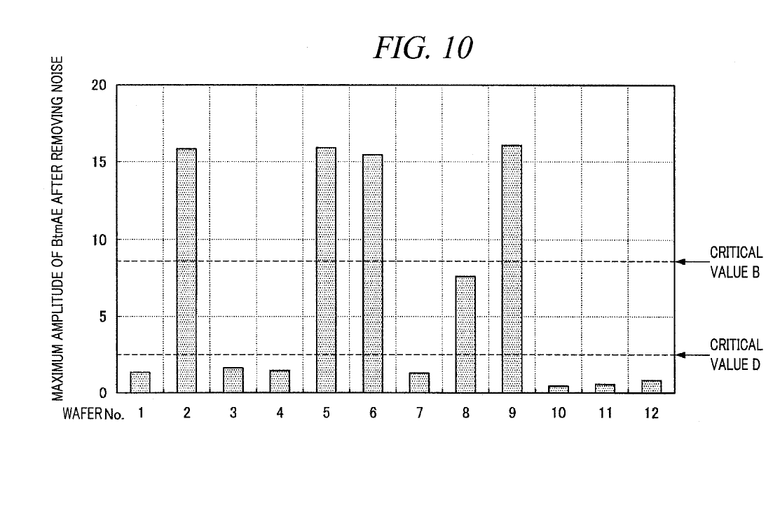

Further, the analysis unit 74 passes the frequency-analyzed data through the noise removing filter 62. FIG. 10 is a graph comparing a maximum amplitude of the noise-removed AE signal BtmAE and the critical value B. According to FIG. 10, the abnormality determination unit 75 determines that there is an abnormal electric discharge on the wafer 2, the wafer 5, the wafer 6, and the wafer 9 where the maximum amplitude of the noise-removed AE signal BtmAE is greater than the critical value B. Further, the abnormality determination unit 75 determines that there is an abnormal electric discharge of low level on the wafer 8 where the maximum amplitude of the noise-removed AE signal BtmAE is smaller than the critical value B. However, in the abnormality detecting method in accordance with the present illustrative embodiment, even if an abnormal electric discharge is detected from only one wafer, the plasma process is controlled to stop immediately. It is determined that there is an abnormal electric discharge if the maximum amplitude of the noise-removed AE signal BtmAE is greater than the critical value D, and a magnitude of the abnormal electric discharge corresponds to a magnitude of the maximum amplitude of the noise-removed BtmAE. That is, it is determined that there is an abnormal electric discharge of relatively high level if the maximum amplitude of the noise-removed AE signal BtmAE is greater than the critical value B. Further, it is determined that there is an abnormal electric discharge of relatively low level if the maximum amplitude of the noise-removed AE signal BtmAE is greater than the critical value D.

It can be seen from a comparison between the above-described result and the wafer defect test result that when the DC high voltage power HV is reversely applied, the wafers on which there is generated an abnormal waveform in the AE signal BtmAE are identical to the wafers on which there is formed an arcing mark. Further, it can be seen that there is a correlation among the maximum amplitude of the high frequency signal, the maximum amplitude of the AE signal BtmAE, and a magnitude of the arcing mark.

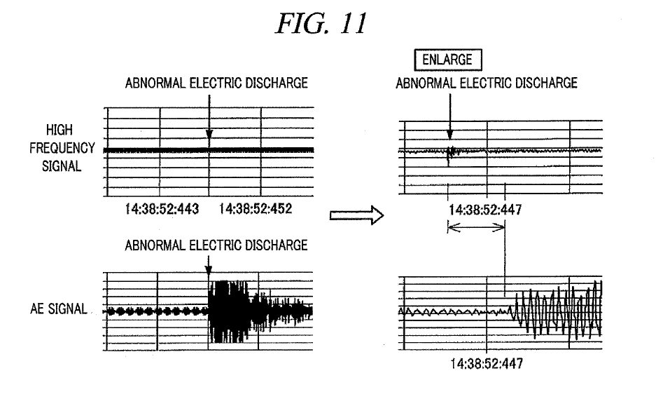

Since the AE sensor 61 is highly sensitive, the AE signal detected by the AE sensor 61 may contain a noise such as a mechanical vibration caused by opening/closing the transfer gate valve 36 and by vertically moving the transfer pin for transferring the wafer in the plasma processing apparatus 10 as well as the signal caused by the plasma abnormal electric discharge. Therefore, the noise contained in the AE signal may cause a decrease in detection accuracy of a plasma abnormal electric discharge. In this regard, in the abnormality detecting method in accordance with the present illustrative embodiment, both the high frequency signal and the AE signal are analyzed. Then, if the abnormal electric discharge is detected based on the analysis results, the plasma process is controlled to stop immediately. By way of example, it may be possible to determine whether or not there is an abnormal electric discharge by comparing the maximum amplitude generation time of the high frequency signal with the maximum amplitude generation time of the AE signal as well as the amplitude magnitudes of the respective signals. Since the AE sensor 61 detects the mechanical vibration, a propagation velocity of the mechanical vibration from a position where the abnormal electric discharge occurs toward the AE sensor 61 varies depending on where the AE sensor 61 is located or how the AE sensor 61 is provided. Therefore, for example, as depicted in FIG. 11, there is made a difference between an abnormal peak generation time of the high frequency signal and an abnormal peak generation time of the AE signal.

To be specific, in order to compare the maximum amplitude generation time of the high frequency signal with the maximum amplitude generation time of the AE signal, it is determined whether or not there is the abnormal peak among the sampled data of the AE signal in step S525 instead of performing step S510 depicted in FIG. 5. If it is determined that there is the abnormal peak, the process proceeds to step S510 and it is determined whether or not there is the abnormal peak among sampled data of the high frequency signal. If it is determined that there is the abnormal peak in step S510, the maximum amplitude generation time of the high frequency signal and the maximum amplitude generation time of the AE signal are compared with each other. If the difference in the maximum amplitude generation times is greater than a predetermined critical value, it is determined that the AE signal contains a noise. If the difference in the maximum amplitude generation times is equal to or smaller than the predetermined critical value, it is determined that there is the abnormal electric discharge. In this way, the noise contained in the AE signal can be removed based on the analysis result of the high frequency signal, so that it is possible to increase the detection accuracy of the plasma abnormal electric discharge. Further, the abnormal electric discharge may be detected based on the analysis result of the high frequency signal only. However, it is not desirable to detect the abnormal electric discharge based on the analysis result of the AE signal only since the noise cannot be removed.

In the abnormality detecting unit 70 in accordance with the present illustrative embodiment, it is possible to detect the minute abnormal electric discharge from sampled data. Such real-time detection makes it possible to stop the abnormal process at an early stage, so that it is possible to prevent the decrease in production yield.

Further, in the abnormality detecting method in accordance with the present illustrative embodiment, the sampled data are collected during the wafer deviation during which the abnormal electric discharge is likely to occur on the wafer W. Therefore, it is possible to analyze only necessary sampled data. As a result, the process load is decreased and the efficiency becomes high.

In the above-described illustrative embodiment, the directional coupler 60 is used to detect the high frequency signal, but the method for detecting the high frequency signal is not limited thereto. By way of example, a so-called RF sensor such as an RF probe configured to detect a high frequency voltage or a current probe configured to detect a high frequency current may be used to detect the high frequency signal. Further, the RF sensor includes the directional coupler 60.

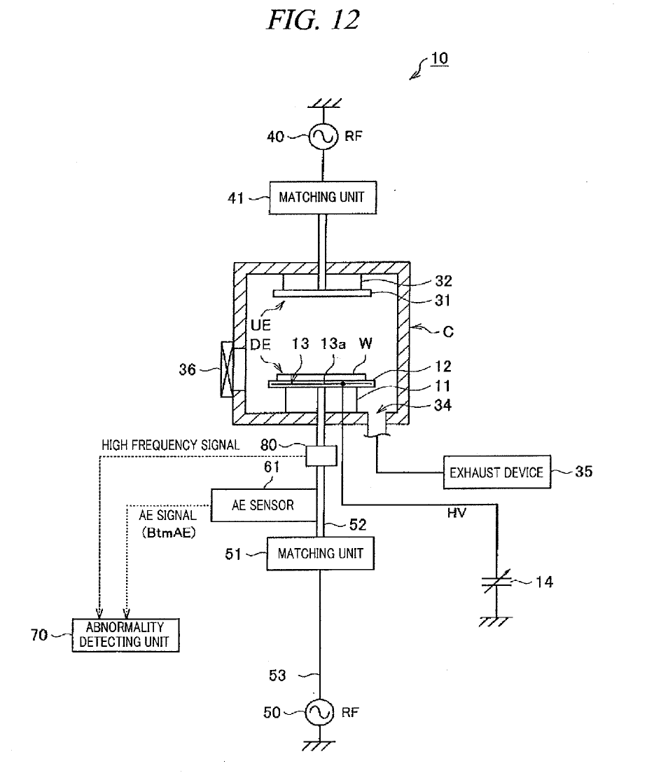

If a RF sensor is used instead of the directional coupler 60, as depicted in FIG. 12, an RF sensor 80 may be connected between the matching unit 51 of the second high frequency power supply 50 and the mounting table 12, and more specifically connected to the power supply rod 52. The RF sensor 80 is arranged at a position closer to the mounting table 12 serving as the lower electrode DE, so that it is possible to detect the high frequency signal with more accuracy. Further, even if the RF probe or the current probe is used, the abnormality detecting unit 70 may carry out the detecting operation of the abnormal electric discharge in the same manner as described above.

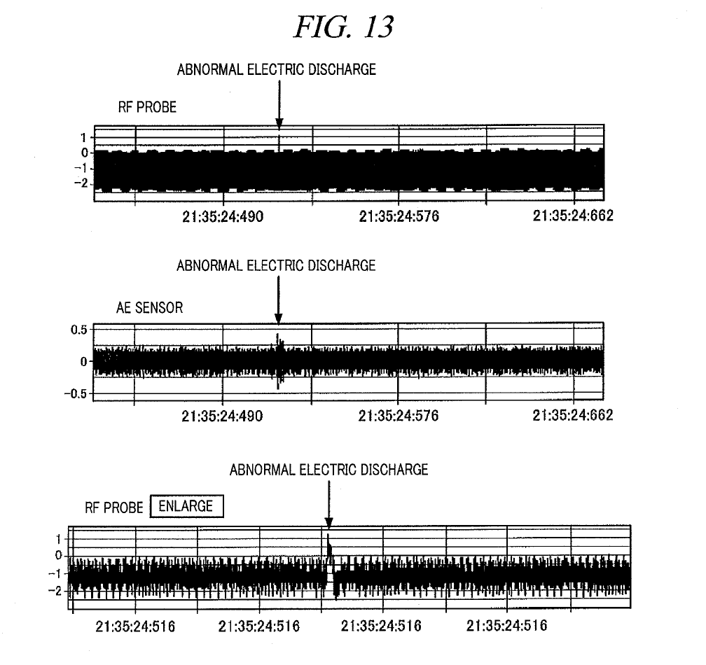

FIG. 13 illustrates an example of data sampled by using the RF probe as an RF sensor 80. A horizontal axis of each graph in FIG. 13 represents time and a vertical axis thereof represents voltage. Each of graphs of FIG. 13 shows data detected from the RF probe, the AE signal BtmAE, and an enlarged time axis of the data detected from the RF probe, in this sequence from the top.

If the wafer defect test is performed on the wafers from which the abnormal waveform shown in FIG. 13 is detected, the electric discharge mark can be =found. Therefore, even if other sensors are used as the RF sensor 80 instead of the directional coupler 60, it is found out that it is possible to determine whether or not there is the abnormal electric discharge.

### Modification Example

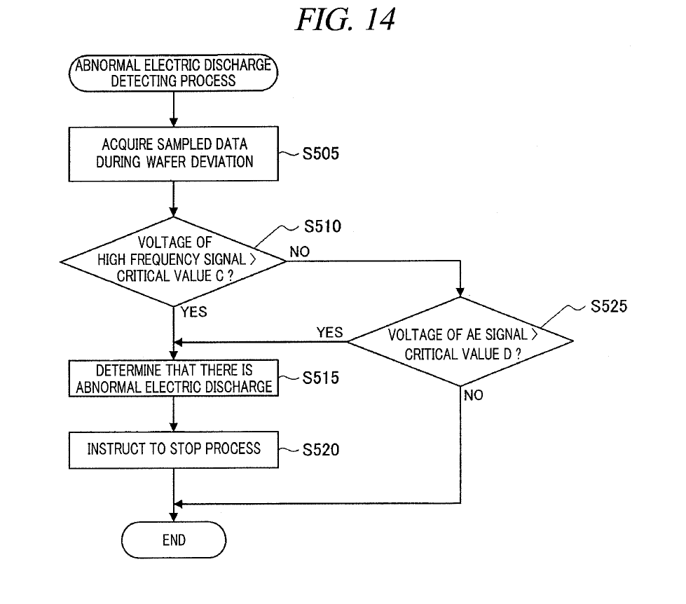

The abnormal electric discharge detecting operation of the abnormality detecting unit 70 in accordance with a modification example of the illustrative embodiment will be explained with reference to FIG. 14. FIG. 14 is a flow chart showing an abnormality detecting process performed in the abnormality detecting unit 70 in accordance with the modification example of the illustrative embodiment.

In the abnormality detecting process in accordance with the modification example, the analysis unit 74 acquires sampled data acquired by the acquisition unit 73 during the wafer deviation (step S505). Then, the abnormality determination unit 75 determines whether or not there is an abnormal peak having a value greater than the predetermined critical value C (see FIG. 7) among the sampled data of high frequency signal (step S510). If there is an abnormal peak, the abnormality determination unit 75 determines that there is an abnormal electric discharge on the wafer W (step S515) and instructs the plasma process controller 71 to stop the process (step S520), and then the abnormal electric discharge detecting process is ended.

In step S510, if there is no abnormal peak having a value greater than the predetermined critical value C among the sampled data of the high frequency signal, the abnormality determination unit 75 determines whether or not there is an abnormal peak having a value greater than the predetermined critical value D among the sampled data of the AE signal (step S525). If there is an abnormal peak, the abnormality determination unit 75 determines that there is an abnormal electric discharge on the wafer W (step S515) and instructs the plasma process controller 71 to stop the process (step S520), and then the abnormal electric discharge detecting process is ended.

In accordance with the modification example, there is generated an abnormal electric discharge if the abnormal peak values are greater than the critical values C and D depicted in FIGS. 7 and 10. Here, if the peak values are smaller than the critical values A and B, it is determined that there is an abnormal electric discharge of relatively low level. Meanwhile, if the peak values are greater than the critical values A and B, it is determined that there is an abnormal electric discharge of relatively high level. Through the FDC (Fault Detection and Classification), it is possible to investigate causes and prepare countermeasures of the abnormal electric discharge.

However, the abnormal electric discharge of low level may cause a decrease in production yield. Thus, if abnormal peak values are smaller than the critical values A and B and greater than the critical values C and D, it is regarded as “abnormal electric discharge” and the plasma processing apparatus needs to be stopped.

The illustrative embodiments are explained in detail with reference to the accompanying drawings, but the present disclosure is not limited thereto. It would be understood by those skilled in the art that various changes and modifications may be made in the scope of the inventive concept defined by the following claims and their equivalents are included in the scope of the inventive concept.

Although there has been explained an example where the abnormality detecting unit in accordance with the illustrative embodiments is used in the etching apparatus, the abnormality detecting unit in accordance with the illustrative embodiments is not limited thereto. The abnormality detecting unit can be used in, for example, a film forming apparatus and an ashing apparatus. As for a plasma source for the plasma processing apparatus, various kinds of plasma such as microwave plasma, magnetron plasma, and ICP plasma may be used instead of parallel plate type plasma as described in the above illustrative embodiments.

1. An abnormality detecting unit comprising:
an acquisition unit configured to acquire a high frequency signal outputted from an RF sensor provided between a matching unit of a high frequency power supply for applying a high frequency power into a processing chamber in which a plasma process is performed on a processing target object and a lower electrode serving as a mounting table for mounting thereon the processing target object, and an AE signal outputted from an AE sensor for detecting acoustic emission occurring in the processing chamber;
an analysis unit configured to analyze a waveform pattern of the high frequency signal and a waveform pattern of the AE signal; and
an abnormality determination unit configured to determine whether or not there is an abnormal electric discharge based on an analysis result of the waveform pattern of the high frequency signal and an analysis result of the waveform pattern of the AE signal.

2. The abnormality detecting unit of claim 1,
wherein the analysis unit is configured to extract a maximum amplitude of the high frequency signal and a maximum amplitude of the AE signal based on the waveform pattern of the high frequency signal and the waveform pattern of the AE signal, and
the abnormality determination unit is configured to determine whether or not there is an abnormal electric discharge by comparing the maximum amplitude of the high frequency signal with a first critical value and by comparing the maximum amplitude of the AE signal with a second critical value.

3. The abnormality detecting unit of claim 1,
wherein the RF sensor is any one of a directional coupler, an RF probe, and a current probe.

4. An abnormality detecting unit comprising:
a monitoring unit configured to monitor an operation from a deviation starting point of a processing target object to an opening point of a transfer gate valve after a plasma process is performed on the processing target object provided in a processing chamber and to specify the operation as a deviation operation of the processing target object;
an acquisition unit configured to acquire a high frequency signal of at least one of a progressive wave and a reflection wave outputted from a directional coupler provided between a high frequency power supply for applying a high frequency power into the processing chamber and a matching unit or between a lower electrode serving as a mounting table for mounting thereon the processing target object and the matching unit during the deviation operation of the processing target object;
an analysis unit configured to analyze a waveform pattern of the high frequency signal; and
an abnormality determination unit configured to determine whether or not there is an abnormal electric discharge based on an analysis result of the waveform pattern of the high frequency signal.

5. The abnormality detecting unit of claim 4,
wherein the acquisition unit is configured to acquire an AE signal outputted from an AE sensor for detecting acoustic emission (AE) occurring in the processing chamber,
the analysis unit is configured to analyze a waveform pattern of the AE signal, and
the abnormality determination unit is configured to determine whether or not there is an abnormal electric discharge based on the analysis result of the waveform pattern of the high frequency signal and an analysis result of the waveform pattern of the AE signal.

6. The abnormality detecting unit of claim 5,
wherein the analysis unit is configured to extract a maximum amplitude of the high frequency signal and a maximum amplitude of the AE signal based on the waveform pattern of the high frequency signal and the waveform pattern of the AE signal during the deviation operation of the processing target object, and
the abnormality determination unit is configured to determine whether or not there is an abnormal electric discharge by comparing the maximum amplitude of the high frequency signal with a first critical value and by comparing the maximum amplitude of the AE signal with a second critical value.

7. The abnormality detecting unit of claim 2,
wherein the abnormality determination unit is configured to determine whether or not there is an abnormal electric discharge by comparing a maximum amplitude generation time of the high frequency signal with a maximum amplitude generation time of the AE signal.

8. The abnormality detecting unit of claim 1,
wherein the analysis unit is configured to perform a frequency analysis on the waveform pattern of the AE signal, remove a noise from the frequency-analyzed data by using a noise removing filter, and analyze the noise-removed data.

9. The abnormality detecting unit of claim 1,
wherein the AE sensor is provided at a power supply rod that supplies a high frequency power to the lower electrode serving as the mounting table for mounting thereon the processing target object.

10. The abnormality detecting unit of claim 1,
wherein sampling of the high frequency signal is performed at intervals ranging from every 1 μsec to every 5 μsec.

11. The abnormality detecting unit of claim 1,
wherein sampling of the AE signal is performed at intervals ranging from every 1 μsec to every 1 msec.

12. The abnormality detecting unit of claim 4,
wherein when a DC high voltage power applied to an electrode embedded in an electrostatic chuck is off or when the DC high voltage power is reversely applied, the monitoring unit determines that it is the deviation starting point of the processing target object after the plasma process is performed.

13. An abnormality detecting method comprising:
acquiring a high frequency signal outputted from an RF sensor provided between a matching unit of a high frequency power supply for applying a high frequency power into a processing chamber in which a plasma process is performed on a processing target object and a lower electrode serving as a mounting table for mounting thereon the processing target object, and an AE signal outputted from an AE sensor for detecting acoustic emission occurring in the processing chamber;
analyzing a waveform pattern of the high frequency signal and a waveform pattern of the AE signal; and
determining whether or not there is an abnormal electric discharge based on an analysis result of the waveform pattern of the high frequency signal and an analysis result of the waveform pattern of the AE signal.

14. An abnormality detecting method comprising:
monitoring an operation from a deviation starting point of a processing target object to an opening point of a transfer gate valve after a plasma process is performed on the processing target object provided in a processing chamber and specifying the operation as a deviation operation of the processing target object;
acquiring a high frequency signal of at least one of a progressive wave and a reflection wave outputted from a directional coupler provided between a high frequency power supply for applying a high frequency power into the processing chamber and a matching unit or between a lower electrode serving as a mounting table for mounting thereon the processing target object and the matching unit during the deviation operation of the processing target object;
analyzing a waveform pattern of the high frequency signal; and
determining whether or not there is an abnormal electric discharge based on an analysis result of the waveform pattern of the high frequency signal.

15. A plasma processing apparatus comprising:
a processing chamber configured to process a processing target object therein;
a plasma generating unit configured to generate plasma in the processing chamber; and
an abnormality detecting unit connected to a power supply unit of the plasma generating unit and configured to detect an abnormality of the plasma,
wherein the abnormality detecting unit comprises:
an acquisition unit configured to acquire a high frequency signal outputted from an RF sensor provided between a matching unit of a high frequency power supply for applying a high frequency power into the processing chamber in which a plasma process is performed on the processing target object and a lower electrode serving as a mounting table for mounting thereon the processing target object, and an AE signal outputted from an AE sensor for detecting acoustic emission occurring in the processing chamber;
an analysis unit configured to analyze a waveform pattern of the high frequency signal and a waveform pattern of the AE signal; and
an abnormality determination unit configured to determine whether or not there is an abnormal electric discharge based on an analysis result of the waveform pattern of the high frequency signal and an analysis result of the waveform pattern of the AE signal.
